(19) United States
(12) Patent Application Publication
(10) Pub. No.: US 2025/0137119 A1
(43) Pub. Date: May 1, 2025

(54) DEPOSITION OF CARBON GAPFILL MATERIALS

(71) Applicant: Applied Materials, Inc., Santa Clara, CA (US)

(72) Inventors: Bhargav S. CITLA, Fremont, CA (US); Shreyas SHUKLA, Sunnyvale, CA (US); Srinivas D. NEMANI, Sunnyvale, CA (US); Ellie Y. YIEH, San Jose, CA (US)

(21) Appl. No.: 18/495,330

(22) Filed: Oct. 26, 2023

(51) Int. Cl. C23C 16/26; C23C 16/04; H01L 21/02; H01L 21/311

(52) U.S. Cl. CPC C23C 16/26; C23C 16/045; H01L 21/02115; H01L 21/02274; H01L 21/0234; H01L 21/31122

(57) ABSTRACT

The present disclosure provides methods and apparatus that facilitate the formation of high-quality carbon gapfill structures and that address the issues related to conventional carbon gapfill methods. In certain embodiments, the carbon gapfill methods and apparatus described herein include plasma enhanced CVD (PECVD) or flowable CVD (FCVD) processes to gapfill structures with high-quality, and stable carbon films.

### BACKGROUND

Integrated circuits are made possible by processes which produce intricately patterned material layers on substrate surfaces. Producing patterned materials on a substrate requires controlled methods of formation and removal of exposed materials.

As device sizes continue to shrink, material formation may affect subsequent operations of semiconductor device fabrication. For example, in certain gapfilling operations, a carbon material may be formed or deposited to fill a trench or other gap formed on a semiconductor substrate. However, as device features are characterized by higher aspect ratios and reduced critical dimensions, these gapfilling operations become increasingly challenging. For example, as carbon is deposited at the top and along sidewalls of a trench, continued deposition thereof may create overhangs that pinch off the trench (including between sidewalls within the trench), and may thereafter result in voids being formed in the trench. This can impact overall device performance and subsequent processing operations.

Thus, there is a need for improved gapfill systems and methods that can be used to produce high quality devices and structures with bottom-up carbon material layers and without voids. These and other needs are addressed by the present technology.

### SUMMARY

The present disclosure provides methods and apparatus that facilitate the formation of high-quality carbon gapfill structures and that address the issues related to conventional carbon gapfill methods. In certain embodiments, the carbon gapfill methods and apparatus described herein include plasma enhanced CVD (PECVD) or flowable CVD (FCVD) processes to gapfill structures with high-quality and stable carbon films.

In certain embodiments, a processing method is provided, the processing method comprising: selectively depositing a film onto a structure of a semiconductor substrate disposed in a processing region of a semiconductor processing chamber, the film comprising a carbon material; exposing the semiconductor substrate to pulsed bias plasma treatment to selectively densify the carbon material of the film deposited at a bottom of the structure; and selectively etching the film from a sidewall of the structure.

In certain embodiments, a processing method is provided, the processing method comprising: forming a first plasma from a carbon-containing precursor, the formation of the first plasma remote from a processing region of a semiconductor processing chamber; depositing a flowable film onto a structure of a semiconductor substrate disposed in the processing region with plasma effluents of the carbon-containing precursor, wherein the flowable film flows into one or more gaps of the structure; forming a second plasma in the processing region; and densifying the flowable film in the one or more gaps of the structure with plasma effluents from the second plasma.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic cross-sectional view of an exemplary processing chamber, according to certain embodiments of the present disclosure.

FIG. 2 illustrates exemplary operations in a processing method, according to certain embodiments of the present disclosure.

FIGS. 3A-3D illustrate schematic cross-sectional views of a substrate during a processing, according to certain embodiments of the present disclosure.

FIG. 4 illustrates exemplary operations in a processing method, according to certain embodiments of the present disclosure.

FIGS. 5A-5C illustrate schematic cross-sectional views of a substrate during a processing, according to certain embodiments of the present disclosure.

Several of the Figures include schematic illustrations. It is to be understood that the Figures are for illustrative purposes, and are not to be considered of scale unless specifically stated to be of scale. Additionally, as schematic illustrations, the Figures are provided to aid in comprehension of the description and may not include all aspects or information compared to realistic representations, and may include exaggerated material for illustrative purposes.

In the appended Figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Carbon gapfill processes are essential in a wide range of patterning applications for forming semiconductor device features, and particularly, for advanced nodes such as A14 nodes and beyond. However, as overall dimensions of semiconductor devices continue to shrink, material layers need to be reduced in thickness and size to scale the features of such devices. And, as the device features are reduced in size, the aspect ratios of the features increase. Conventional gapfill processes, and particularly, carbon gapfill processes, may be ineffective in uniformly filling gaps between these high aspect ratio features with high-quality carbon material layers and without leaving voids.

For example, current spin-on carbon gapfill processes suffer from issues related to thin film planarization, etch selectivity, and undesired oxidization of the carbon gapfill material. Further, carbon deposited by chemical vapor deposition (CVD) is typically not flowable, leading to voids formed in carbon gapfills. For example, when CVD carbon is deposited on a feature, such as a trench or other gap, the carbon may form overhangs near the top of the feature to seal or obstruct the feature prior to filling the feature, thus leading to the formation of a void underneath the obstructed top. Accordingly, conventional carbon gapfill processes have been limited in the ability to prevent structural flaws in the final devices.

The present disclosure provides methods and apparatus that facilitate the formation of high-quality carbon gapfill structures and that address the issues related to conventional carbon gapfill methods. In certain embodiments, the carbon gapfill methods and apparatus utilize plasma enhanced CVD (PECVD) or flowable CVD (FCVD) processes to gapfill structures with high-quality, bottom-up, and stable carbon films.

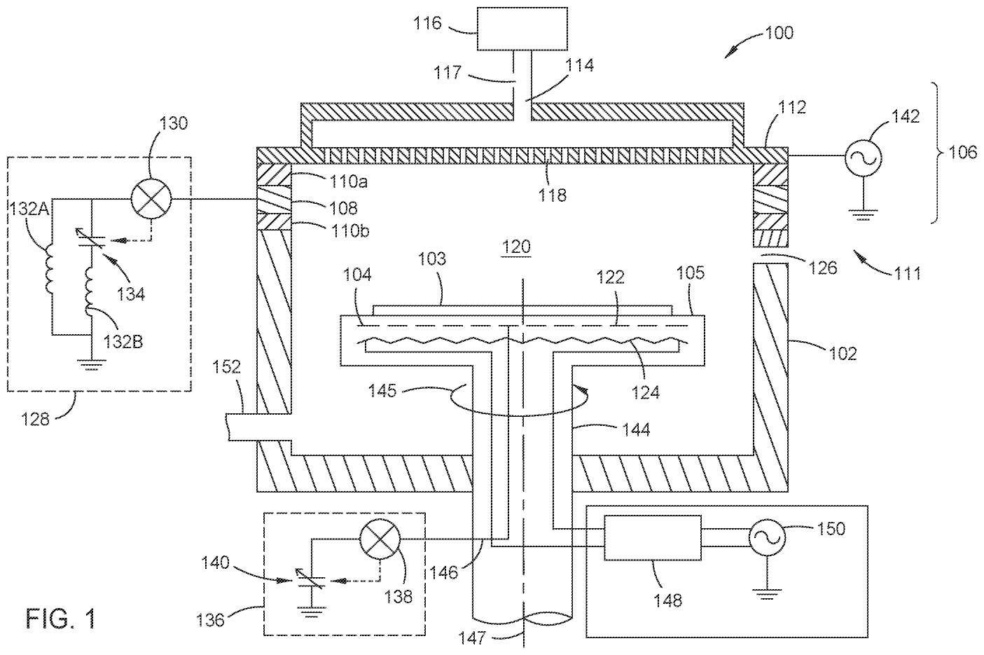

FIG. 1 illustrates a cross-sectional view of an exemplary processing chamber 100, according to certain embodiments of the present disclosure. FIG. 1 provides an overview of a system incorporating one or more aspects of the present disclosure, and/or which may perform one or more deposition or other processing operations according to embodiments of the present disclosure. Additional details of chamber 100 or methods performed may be described further below. Chamber 100 may be utilized to form film layers, e.g., for gapfilling, according to certain embodiments of the present disclosure, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate, as necessary, during a deposition process. Additionally, the substrate support 104 include a cooling device and may be configured to be chilled, e.g., less than or about 100° C., or less than or about 90° C., or less than or about 80° C., or less than or about 70° C., or less than or about 60° C., or less than or about 50° C., or less than or about 40° C., or less than or about 30° C., or less than or about 20° C., or less than or about 10° C., or less.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In certain embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in certain embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In certain embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In certain embodiments, the second source of electric power 150 may be an RF bias power (e.g., configured to provide 2 MHz RF pulsed bias and/or 13.5 MHz RF pulsed bias).

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Inlet 114 may include delivery from a remote plasma source unit 116, which may be fluidly coupled with the chamber, as well as a bypass 117 for process gas delivery that may not flow through the remote plasma source unit 116 in certain embodiments. Gases may exit the processing chamber 100 through an outlet 152. Electric power may be coupled with the gas distributor 112 to establish a plasma in the processing volume 120. The substrate may be subjected to an electrical bias using the third electrode 124 in certain embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

Processing chamber 100 may be utilized in certain embodiments of the present disclosure for processing methods that may include formation, treatment, etching, or conversion of materials for semiconductor structures. It is to be understood that the chamber described is not to be considered limiting, and any chamber that may be configured to perform operations as described may be similarly used.

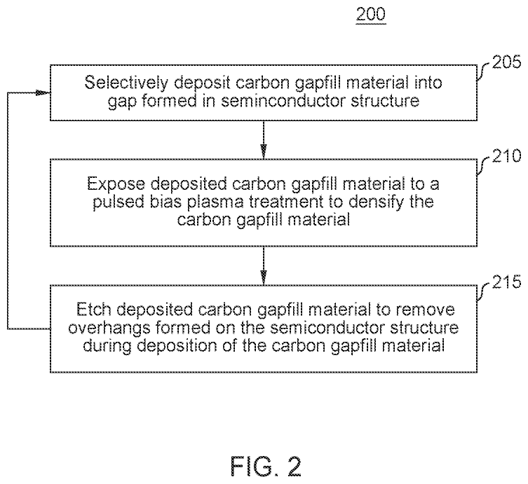

FIG. 2 illustrates a flow diagram of exemplary operations in a processing method 200, according to certain embodiments of the present disclosure. The method 200 generally includes a directional selective fill (DSF) carbon gapfill deposition process, which facilitates deposition of a stable carbon film on structures. The method 200 may be performed in a variety of processing chambers and on one or more mainframes or tools, including processing chamber 100 described above. Method 200 may include a number of optional operations, which may or may not be specifically associated with certain embodiments of methods according to the present technology. For example, certain operations may be described in order to provide a broader scope of the structural formation, but are not critical to the technology, or may be performed by alternative methodology as would be readily appreciated.

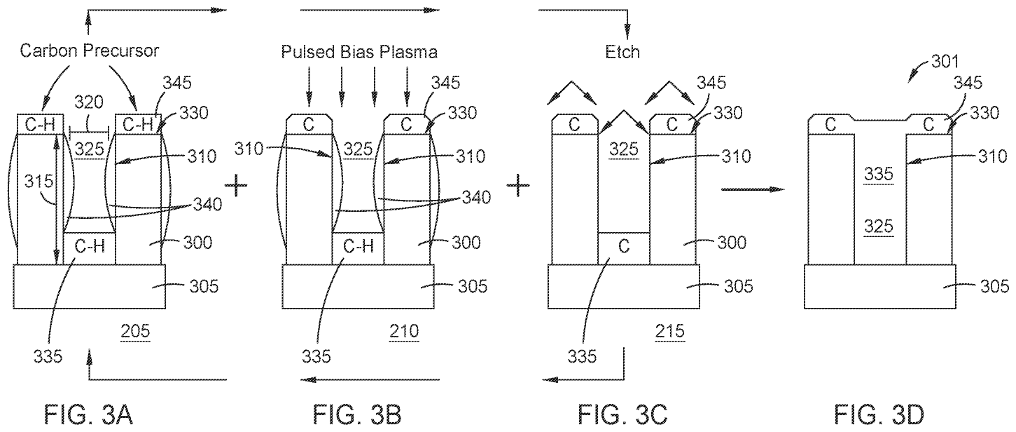

The operations of method 200 are schematically illustrated in FIGS. 3A-3D, the illustrations of which will be described in conjunction with the operations of method 200. It is to be understood that the Figures illustrate only partial schematic views, and that a substrate may contain any number of additional layers, materials, and/or features having a variety of characteristics and aspects as illustrated in the Figures.

In certain embodiments, method 200 may include additional operations prior to initiation of the listed operations in FIG. 2. For example, additional processing operations may include forming structures on a semiconductor substrate, which may include both forming and removing material. For example, transistor structures, memory structures, or any other structures may be formed. Prior processing operations may be performed in the chamber in which method 200 may be performed, e.g., chamber 100, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be placed on a substrate support, which may be a pedestal such as substrate support 104, and which may reside in a processing region of the chamber, such as processing volume 120 described above.

Turning to FIGS. 3A-3D, a partial view of a substrate 305 having a structure 300 formed thereon is shown. Substrate 305 may represent a substrate on which several operations have been performed, and on which semiconductor processing may be performed. It is to be understood that structure 300 may be representative of only a few top layers formed on the substrate 305 during processing to illustrate aspects of the present technology, and that one or more intermediate layers may be disposed between the structure 300 and the substrate 305. Thus, when referencing the substrate 305, the present disclosure may refer to the substrate 305 and/or one or more intermediate layers disposed on the substrate 305 and below the structure 300.

The substrate 305 and/or the structure 300 may include one or more materials used in semiconductor processing. For example, the material(s) may be or include silicon, germanium, dielectric materials including silicon oxide or silicon nitride, other oxide or nitride materials, metal materials, or any number of combinations of these materials. The structure 300 be characterized by any shape or configuration according to the present technology. In certain embodiments, the structure 300 includes a trench or aperture 325 formed on the substrate 305.

Although the structure 300 may be characterized by any shape or size, in certain embodiments, the structure 300 is characterized by a high aspect ratio, or a ratio of a depth 315 of the structure to a width or diameter 320 across the structure. For example, in certain embodiments, structure 300 may be characterized by an aspect ratio greater than or about 5:1, or may be characterized by an aspect ratio greater than or about 10:1, greater than or about 15:1, greater than or about 20:1, greater than or about 25:1, greater than or about 30:1, greater than or about 40:1, greater than or about 50:1, or greater. Additionally, the structure 300 may be characterized by a narrow width or diameter 320 across the structure including between two sidewalls 310, such as a dimension less than or about 20 nm, and may be characterized by a width or diameter 320 across the structure of less than or about 15 nm, less than or about 12 nm, less than or about 10 nm, less than or about 9 nm, less than or about 8 nm, less than or about 7 nm, less than or about 6 nm, less than or about 5 nm, or less. However, in certain embodiments, structure 500 may be characterized by an aspect ratio less than or about 5:1, or may be characterized by an aspect ratio less than or about 5:2, less than or about 5:3, less than or about 5:4, less than or about 1:1, or less. In certain embodiments, the structure 300 may be characterized by a width or diameter greater than or about 20 nm.

Returning to FIG. 2, in certain embodiments, method 200 may include optional treatment operations, such as a pretreatment or pre-clean process, that may be performed to prepare one or more surface(s) of the substrate 305 and/or structure 300 for deposition of a carbon gapfill.

Once the surfaces are prepared, at operation 205 and as shown in FIG. 3A, the method 200 includes selectively depositing a carbon gapfill material into gaps formed in the structure 300, such as trench or aperture 325. In certain embodiments, operation 205 includes delivering one or more precursors to a processing region of a semiconductor processing chamber housing the structure 300. The precursors may include one or more carbon-containing precursors, such as hydrocarbons, as well as one or more diluents or carrier gases such as an inert gas or other gas delivered with the carbon-containing precursor. A plasma may be formed from the deposition precursors, including the carbon-containing precursor. The plasma may be formed within the processing region, which may allow deposition materials to deposit on the substrate. For example, in certain embodiments a capacitively-coupled plasma may be formed within the processing region by applying plasma power to the faceplate as previously described. In certain embodiments, however, the plasma may be formed external to the processing region, such as by a remote plasma source (e.g., remote plasma source unit 116 described above), and delivered to the processing region.

In certain embodiments, the carbon-containing precursor(s) delivered to the processing region include an aliphatic hydrocarbon, such as an alkane, alkene, alkyne, cycloalkane, or alkadiene. Examples of aliphatic hydrocarbon include 1,5-hexadiene, ethylene, propylene, and the like. In certain embodiments, the carbon-containing precursor(s) delivered to the processing region include a vinyl group-based hydrocarbon precursor. Examples of vinyl group-based precursors include 5-vinyl-2-norbornene and other norbornene compounds.

As noted above, a carbon-containing material may be deposited on the structure 300 and/or substrate 305 at operation 205 from plasma effluents of the carbon-containing precursor. The materials may at least partially deposit within gaps formed the structure 300, such as trench or aperture 325, to provide a bottom-up type of gapfill. As illustrated in FIG. 3A, gapfill material 335 may be deposited at the bottom of the structure 300 and on the substrate 305 and, although an amount of material may be deposited on the sidewalls 310 of the structure 300, as illustrated with gapfill material 340, as well as on top of, or between, structure 300, as illustrated by gapfill material 345 on top surface 330 of structure 300. Although the amount deposited may be relatively small, the remaining material on the sidewalls 310 may limit subsequent flow. This may cause the feature to be pinched off, which may form voids within the feature.

The power applied during deposition may be a lower plasma power, which may limit dissociation, and which may maintain an amount of hydrogen incorporation in the deposited materials. Additionally, unlike conventional technologies, the present technology may incorporate a bias process, which may produce a treatment to the deposited film during the deposition operations. The process may include utilizing a source power, such as coupled with the faceplate or showerhead as previously described, as well as utilizing a bias power, such as applied through the substrate support as discussed above.

In certain embodiments, the source power may be pulsed, and the duty cycle may be reduced, which may further reduce the effective plasma power. For example, the source power may be applied at any higher frequency, such as greater than or about 10 MHz, greater than or about 13 MHz, greater than or about 15 MHz, greater than or about 20 MHz, or higher. The source power may deliver a plasma power to the faceplate of less than or about 300 W, and may deliver a power of less than or about 250 W, less than or about 200 W, less than or about 150 W, less than or about 100 W, less than or about 50 W, or less. Additionally, the source power may be pulsed at a pulsing frequency of 20 kHz or less, such as less than or about 15 kHz, less than or about 12 kHz, less than or about 10 kHz, less than or about 8 kHz, or less. Additionally, the pulsing duty cycle may be applied at less than or about 50%, and may be applied at less than or about 40%, less than or about 30%, less than or about 20%, less than or about 10%, less than or about 5%, less than or about 1% or less.

In certain embodiments, a bias power source may be operated at a lower frequency than the source power, and may be operated at less than or about 15 MHz, less than or about 13.5 MHz, less than or about 10 MHz, less than or about 5 MHz, less than or about 2 MHz, or less. The bias power supply may be operated at a power of less than or about 500 W, and may be operated at less than or about 400 W, less than or about 300 W, less than or about 200 W, less than or about 100 W, less than or about 60 W, or less.

In certain embodiments, to facilitate dissociation and deposition, the deposition precursors may include one or more inert gases, such as argon (Ar) and/or helium (He), and/or xenon (Xe), krypton (Kr), and/or the like, which may help improve dissociation. For example, argon may be delivered with the carbon-containing precursor at a flow rate ratio of the argon to the carbon-containing precursor of greater than or about 0.1:1, and may be delivered at a flow rate ratio of greater than or about 0.5:1, greater than or about 0.9:1, greater than or about 1:1, greater than or about 1.8:1, greater than or about 2:1, greater than or about 2.7:1, greater than or about 3.0:1, greater than or about 3.6:1, or more. In certain embodiments, ammonia may be delivered with the carbon-containing precursor and/or argon at a flow rate ratio of the ammonia to the carbon-containing precursor of greater than or about 0.2:1, and may be delivered at a flow rate ratio of greater than or about 0.4:1, greater than or about 0.6:1, greater than or about 0.8:1, greater than or about 1:1, greater than or about 1.2:1, greater than or about 1.4:1, greater than or about 1.6:1, or more.

In certain embodiments, a flow rate of the carbon-containing precursor is greater than or about 100 mg/min, greater than or about 500 mg/min, greater than or about 1000 mg/min, or greater than or about 2000 mg/min, or greater than or about 3000 mg/min, or greater than or about 4000 mg/min, or greater than or about 500 mg/min, or more. In certain embodiments, a flow rate of argon is greater than or about 500 sccm, or greater than or about 1000 sccm, or greater than or about 2000 sccm, or greater than or about 3000 sccm, or greater than or about 4000 sccm, or greater than or about 4500 sccm, or more. In certain embodiments, a flow rate of ammonia is greater than or about 250 sccm, or greater than or about 500 sccm, or greater than or about 750 sccm, or greater than or about 1000 sccm, or more.

In certain embodiments, carbon gapfill material may be deposited on the structure 500 and/or substrate 505 at operation 405 at a controlled deposition rate of about 50 A/min or more, or about 100 A/min or more, about 155 A/min or more, about 200 A/min or more, or more.

Temperature and pressure may also impact deposition of the carbon gapfill material at operation 405. In certain embodiments, operation 405 may be performed at a chamber temperature below or about 100° C., and may be performed at a temperature less than or about 80° C., less than or about 60° C., less than or about 40° C., less than or about 30° C., less than or about 20° C., less than or about 10° C., or lower. In certain embodiments, pressure within the chamber may be kept relatively low, such as at a chamber pressure of less than or about 20 Torr, and pressure may be maintained at less than or about 15 Torr, less than or about 10 Torr, less than or about 5 Torr, less than or about 3 Torr, less than or about 2 Torr, less than or about 1 Torr, less than or about 0.1 Torr, or less.

In certain embodiments, the selective deposition of the carbon gapfill material at operation 205 is carried out for a period of about 5 seconds or more, or about 10 seconds or more, about 15 seconds or more, about 20 seconds or more, about 25 seconds or more, or more.

Once the carbon gapfill material is selectively deposited on the structure 300 and/or substrate 305, at operation 210 of the method 200 and as shown in FIG. 3B, the deposited carbon gapfill material is exposed to a pulsed bias plasma treatment to densify the material. The pulsed bias plasma treatment at operation 210 converts carbon-hydrogen bonds of the carbon gapfill material to carbon-carbon bonds, thereby resulting in a higher density, and thus high quality, carbon film. In certain embodiments, operation 210 is performed in the same chamber as operation 205. In certain embodiments, the substrate 305 and structure 300 formed thereon are transferred to a different chamber upon deposition of the carbon gapfill material to perform operation 210.

In certain embodiments, operation 210 includes delivering one or more precursors to the processing region of the semiconductor processing chamber housing the structure 300 to form a treatment gas mixture. In certain embodiments, the precursors include at least one of hydrogen (H2) or ammonia (NH₃), argon (Ar), and/or helium (He). A plasma may be formed from the treatment gas mixture. The plasma may be formed within the processing region, such as by applying plasma power to the faceplate as previously described. In certain embodiments, however, the plasma may be formed external to the processing region, such as by a remote plasma source (e.g., remote plasma source unit 116 described above), and delivered to the processing region.

The source power may deliver a plasma power to the faceplate at any higher frequency, such as greater than or about 10 MHz, greater than or about 13 MHz, greater than or about 15 MHz, greater than or about 20 MHz, or higher. The source power may deliver a plasma power to the faceplate of less than or about 1500 W, and may deliver a power of less than or about 1250 W, less than or about 1000 W, less than or about 750 W, less than or about 500 W, less than or about 250 W, or less. Additionally, the source power may be pulsed at a pulsing frequency of 20 kHz or less, such as less than or about 15 kHz, less than or about 12 kHz, less than or about 10 kHz, less than or about 8 kHz, or less. Additionally, the pulsing duty cycle may be applied at less than or about 50%, and may be applied at less than or about 40%, less than or about 30%, less than or about 20%, less than or about 10%, less than or about 5%, less than or about 1% or less.

In certain embodiments, to apply biasing during operation 210, a bias power source is operated at less than or about 15 MHz, or less than or about 13.5 MHz, or less than or about 10 MHz, or less than or about 8 MHz, less than or about 6 MHz, or less than or about 4 MHz, or less than or about 2 MHz, or less. The bias power supply may be operated at a power of greater than or about 600 W, and may be operated at greater than or about 800 W, greater than or about 1000 W, greater than or about 1200 W, greater than or about 1400 W, or more. Additionally, the pulsing duty cycle of the bias power source may be applied at less than or about 50%, and may be applied at less than or about 40%, less than or about 30%, less than or about 20%, less than or about 10%, less than or about 6%, less than or about 5%, less than or about 1% or less.

The bias power delivery is utilized during the treatment at operation 210 to create an amount of directionality for movement of generated plasma species, and more specifically, to create a downward movement of plasma effluents toward the structure 300. Thus, the plasma effluents are directed toward surfaces normal to the direction of travel, such as material along the bottom of the structure 300 (e.g., bottom of the trench or aperture 325), as compared to surfaces parallel to the direction of travel (e.g., sidewalls 310). As a result, carbon gapfill material at the bottom of the trench or aperture 325 is densified, while material deposited on sidewalls 310 is not.

In certain embodiments, where the precursors at operation 210 include argon (Ar) and helium (He), argon and helium may be simultaneously delivered to the processing region in a simultaneous argon/helium pulsed bias plasma treatment. In certain embodiments, a flow rate of argon is greater than or about 500 sccm, or greater than or about 1000 sccm, greater than or about 1500 sccm, greater than or about 2000 sccm, greater than or about 2500 sccm, or greater than or about 3000 sccm, or more. In certain embodiments, a flow rate of helium is greater than or about 500 sccm, or greater than or about 750 sccm, greater than or about 1000 sccm, greater than or about 1500 sccm, or greater than or about 2000 sccm, or more. In certain embodiments, argon may be delivered with helium at a flow rate ratio of argon to helium of greater than or about 0.5:1, and may be delivered at a flow rate ratio of greater than or about 1:1, greater than or about 1.5:1, greater than or about 2:1, greater than or about 2.5:1, greater than or about 3.0:1, greater than or about 3.5:1, greater than or about 4.0:1, or more.

In certain embodiments, operation 210 may be performed at a temperature below or about 100° C., and may be performed at a temperature less than or about 80° C., less than or about 60° C., less than or about 40° C., less than or about 30° C., less than or about 20° C., or lower. Pressure within the chamber may be kept relatively low, such as at a chamber pressure of less than or about 5 Torr, and pressure may be maintained at less than or about 1 Torr, less than or about 0.75 Torr, less than or about 0.66 Torr, less than or about 0.5 Torr, less than or about 0.25 Torr, less than or about 0.1 Torr, or less.

In certain embodiments, the pulsed bias plasma treatment at operation 210 is carried out for a period of about 5 seconds or more, or about 10 seconds or more, about 15 seconds or more, about 20 seconds or more, about 25 seconds or more, about 30 seconds or more, or more.

Subsequent to the pulsed bias plasma treatment to densify the deposited carbon gapfill material, an etching process is performed thereon at operation 215 as shown in FIG. 3C. The etching process at operation 215 is performed to remove any material overhangs formed in, or over, the trench or aperture 325 of structure 300 during deposition of the carbon gapfill material at operation 205. Overhangs may pinch off the trench or aperture 325 (including between sidewalls 310 thereof), and may result in voids being formed in the trench or aperture 325 when multiple rounds of deposition are performed. This can impact overall device performance and subsequent processing operations.

In certain embodiments, operation 215 is performed in the same chamber as operation 205 and/or operation 210. In certain embodiments, the substrate 305 and structure 300 formed thereon are transferred to a different chamber from operation 205 and/or operation 210 upon densifying the carbon gapfill material to perform operation 215.

In certain embodiments, the etching process at operation 215 includes a plasma-based etching process, such as a dry chemical etching process selective for low-density carbon (e.g., carbon gapfill material deposited on sidewalls 310 that has not been densified at operation 210). In certain embodiments, the plasma at operation 215 is formed from oxygen (O₂) and argon (Ar) precursors. In certain embodiments, where the precursors at operation 215 include oxygen and argon, oxygen may be delivered with argon at a flow rate ratio of argon to oxygen of greater than or about 0.5:1, and may be delivered at a flow rate ratio of greater than or about 1:1, greater than or about 1.5:1, greater than or about 2:1, greater than or about 2.5:1, greater than or about 3.0:1, greater than or about 3.5:1, greater than or about 4.0:1, greater than or about 4.5:1, greater than or about 5.0:1, greater than or about 5.5:1, or more. In certain embodiments, a flow rate of argon is greater than or about 200 sccm, greater than or about 250 sccm, greater than or about 500 sccm, greater than or about 750 sccm, or greater than or about 1000 sccm, or greater than or about 1250 sccm, or more. In certain embodiments, a flow rate of oxygen is greater than or about 50 sccm, or greater than or about 100 sccm, greater than or about 150 sccm, greater than or about 200 sccm, or greater than or about 250 sccm, or more.

In certain embodiments, operation 215 may be performed at a temperature below or about 100° C., and may be performed at a temperature less than or about 80° C., less than or about 60° C., less than or about 40° C., less than or about 30° C., less than or about 20° C., or lower. Pressure within the chamber may be kept relatively low, such as at a chamber pressure of less than or about 5 Torr, and pressure may be maintained at less than or about 1 Torr, less than or about 0.75 Torr, less than or about 0.66 Torr, less than or about 0.5 Torr, less than or about 0.25 Torr, less than or about 0.1 Torr, or less.

In further embodiments, the etching process at operation 215 includes a reactive ion etch, a wet etch, or the like.

After performance of operation 215, operations 205-215 of the method 200 may be repeated as needed until the trench or aperture 325 of structure 300 has a desired amount of carbon gapfill material formed therein, thereby resulting in a gapfilled structure 301 as shown in FIG. 3D. The gapfilling process described with reference to method 200 facilitates the formation of a high-quality and stable carbon film that mitigates or overcomes many of the issues of conventional carbon gapfilling processes. In certain embodiments, after performance of operation 215, the gapfilled structure 301 may be exposed to additional operations to fabricate a completed semiconductor device, including formation of additional structures on substrate 305.

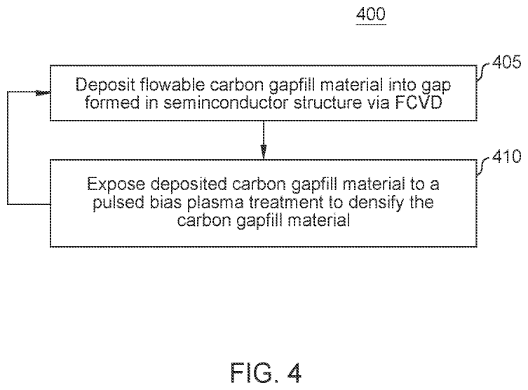

FIG. 4 illustrates a flow diagram of exemplary operations in another processing method 400, according to certain embodiments of the present disclosure. The method 400 generally includes a flowable chemical vapor deposition (FCVD) carbon gapfill deposition process, which facilitates deposition of a stable carbon film on structures. The method 400 may be performed in a variety of processing chambers and on one or more mainframes or tools, including processing chamber 100 described above. Method 400 may include a number of optional operations, which may or may not be specifically associated with certain embodiments of methods according to the present technology. For example, certain operations may be described in order to provide a broader scope of the structural formation, but are not critical to the technology, or may be performed by alternative methodology as would be readily appreciated.

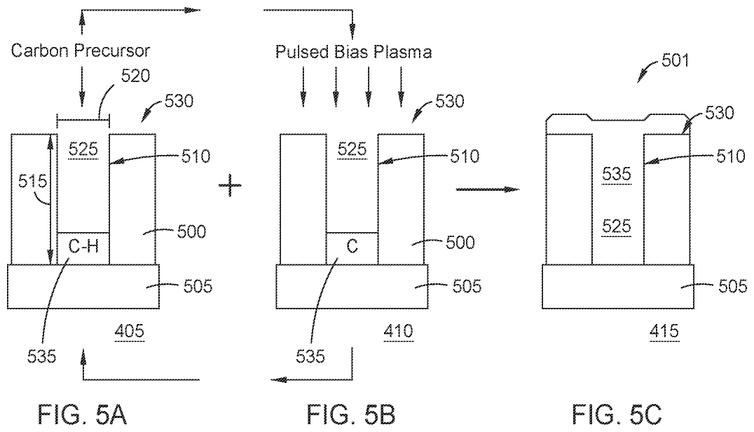

The operations of method 400 are schematically illustrated in FIGS. 5A-5C, the illustrations of which will be described in conjunction with the operations of method 400. It is to be understood that the Figures illustrate only partial schematic views, and that a substrate may contain any number of additional layers, materials, and/or features having a variety of characteristics and aspects as illustrated in the Figures.

In certain embodiments, method 400 may include additional operations prior to initiation of the listed operations in FIG. 4. For example, additional processing operations may include forming structures on a semiconductor substrate, which may include both forming and removing material. For example, transistor structures, memory structures, or any other structures may be formed. Prior processing operations may be performed in the chamber in which method 400 may be performed, e.g., chamber 100, or processing may be performed in one or more other processing chambers prior to delivering the substrate into the semiconductor processing chamber or chambers in which method 400 may be performed. Regardless, method 400 may optionally include delivering a semiconductor substrate to a processing region of a semiconductor processing chamber, such as processing chamber 100 described above, or other chambers that may include components as described above. The substrate may be placed on a substrate support, which may be a pedestal such as substrate support 104, and which may reside in a processing region of the chamber, such as processing volume 120 described above.

Turning to FIGS. 5A-5C, a partial view of a substrate 505 having a structure 500 formed thereon is shown. Substrate 505 may represent a substrate on which several operations have been performed, and on which semiconductor processing may be performed. It is to be understood that structure 500 may be representative of only a few top layers formed on the substrate 505 during processing to illustrate aspects of the present technology, and that one or more intermediate layers may be disposed between the structure 500 and the substrate 505. Thus, when referencing the substrate 505, the present disclosure may refer to the substrate 505 and/or one or more intermediate layers disposed on the substrate 505 and below the structure 500.

Like the substrate 305 and/or structure 300, the substrate 505 and/or the structure 500 may include one or more materials used in semiconductor processing. For example, the material(s) may be or include silicon, germanium, dielectric materials including silicon oxide or silicon nitride, other oxide or nitride materials, metal materials, or any number of combinations of these materials. The structure 300 be characterized by any shape or configuration according to the present technology. In certain embodiments, the structure 500 includes a trench or aperture 525 formed on the substrate 505.

Although the structure 500 may be characterized by any shape or size, in certain embodiments, the structure 500 is characterized by a high aspect ratio, or a ratio of a depth 515 of the structure to a width or diameter 520 across the structure. For example, in certain embodiments, structure 500 may be characterized by an aspect ratio greater than or about 5:1, or may be characterized by an aspect ratio greater than or about 10:1, greater than or about 15:1, greater than or about 20:1, greater than or about 25:1, greater than or about 30:1, greater than or about 40:1, greater than or about 50:1, or greater. Additionally, the structure 500 may be characterized by a narrow width or diameter 520 across the structure including between two sidewalls 510, such as a dimension less than or about 20 nm, and may be characterized by a width or diameter 520 across the structure of less than or about 15 nm, less than or about 12 nm, less than or about 10 nm, less than or about 9 nm, less than or about 8 nm, less than or about 7 nm, less than or about 6 nm, less than or about 5 nm, or less. However, in certain embodiments, structure 500 may be characterized by an aspect ratio less than or about 5:1, or may be characterized by an aspect ratio less than or about 5:2, less than or about 5:3, less than or about 5:4, less than or about 1:1, or less. In certain embodiments, the structure 500 may be characterized by a width or diameter greater than or about 20 nm.

Returning to FIG. 4, in certain embodiments, method 400 may include optional treatment operations, such as a pretreatment or pre-clean process, that may be performed to prepare one or more surface(s) of the substrate 505 and/or structure 500 for deposition of a carbon gapfill.

Once the surfaces are prepared, at operation 405 and as shown in FIG. 4A, the method 400 includes depositing, via FCVD, a flowable carbon gapfill material into gaps formed in the structure 500, such as trench or aperture 525. In certain embodiments, operation 405 includes a remote plasma-based flowable carbon deposition process, wherein the plasma is formed external to a processing region of a semiconductor processing chamber housing the substrate 505, such as by a remote plasma source (e.g., remote plasma source unit 116 described above), and then delivered to the processing region. In certain embodiments, the plasma is formed within the processing region, such as by delivering one or more precursors to the processing region and applying plasma power to the faceplate to form a capacitively-coupled plasma.

In certain embodiments, the precursors may include one or more carbon-containing precursors, such as hydrocarbons, as well as one or more diluents or carrier gases such as an inert gas or other gas delivered with the carbon-containing precursor. A plasma may be formed from the deposition precursors, including the carbon-containing precursor(s). In certain embodiments, the carbon-containing precursor(s) at operation 405 include an aliphatic hydrocarbon, such as an alkane, alkene, alkyne, cycloalkane, or alkadiene. Examples of aliphatic hydrocarbons include 1,5-hexadiene, ethylene, propylene, and the like. In certain embodiments, the carbon-containing precursor(s) delivered to the processing region include a vinyl group-based hydrocarbon precursor. Examples of vinyl group-based precursors include 5-vinyl-2-norbornene and other nonbornene compounds.

In certain embodiments, the deposition precursors may further include one or more additional precursors, such as argon (Ar) and/or ammonia (NH₃), and/or helium (He), xenon (Xe), krypton (Kr), nitrogen (N₂), hydrogen (H₂), or the like. For example, argon may be delivered with the carbon-containing precursor at a flow rate ratio of the argon to the carbon-containing precursor of greater than or about 0.5:1, and may be delivered at a flow rate ratio of greater than or about 1:1, greater than or about 1.5:1, greater than or about 2:1, greater than or about 2.5:1, greater than or about 3.0:1, greater than or about 3.5:1, greater than or about 4.0:1, or more. In certain embodiments, a flow rate of the carbon-containing precursor is greater than or about 500 mg/min, or greater than or about 750 mg/min, or greater than or about 1000 mg/min, or more. In certain embodiments, a flow rate of an inert gas is greater than or about 500 sccm, or greater than or about 750 sccm, or greater than or about 1000 sccm, or more.

In certain embodiments, flowable carbon gapfill material may be deposited on the structure 300 and/or substrate 305 at operation 205 at a controlled deposition rate of about 50 A/min or more, or about 100 A/min or more, or about 200 A/min or more, or about 300 A/min or more, about 400 A/min or more, about 440 A/min or more, about 500 A/min or more, or more.

Temperature and pressure may also impact deposition of the flowable carbon gapfill material at operation 205. In certain embodiments, operation 205 may be performed at a temperature below or about 100° C., and may be performed at a temperature less than or about 80° C., less than or about 60° C., less than or about 40° C., less than or about 30° C., less than or about 20° C., or lower. Additionally, the substrate support or pedestal supporting the substrate 505 and structure 500 (e.g., substrate support 104) may be chilled during operation 405, such as to a temperature of less than or about 100° C., or less than or about 80° C., less than or about 60° C., less than or about 40° C., less than or about 30° C., less than or about 20° C., or lower.

Pressure within the chamber may be kept relatively low, such as at a chamber pressure of less than or about 20 Torr, and pressure may be maintained at less than or about 15 Torr, less than or about 10 Torr, less than or about 5 Torr, less than or about 3 Torr, less than or about 2 Torr, less than or about 1 Torr, less than or about 0.8 Torr, less than or about 0.1 Torr, or less.

In certain embodiments, the deposition of the flowable carbon gapfill material at operation 405 is carried out for a period of about 60 seconds or more, or about 90 seconds or more, about 120 seconds or more, about 150 seconds or more, about 180 seconds or more, about 210 seconds or more, about 240 seconds or more, about 270 seconds or more, about 300 seconds or more, or more.

As noted above, a flowable carbon-containing material may be deposited on the structure 500 and/or substrate 505 at operation 405 from plasma effluents of the carbon-containing precursor. The materials may at least partially deposit and flow into gaps formed the structure 500, such as trench or aperture 525, to provide a bottom-up type of gapfill. As illustrated in FIG. 5A, gapfill material 535 may be deposited and/or flow to the bottom of the structure 500 and on the substrate 505 at operation 405.

Once the flowable carbon gapfill material is deposited on the structure 500 and/or substrate 505, at operation 410 of the method 400 and as shown in FIG. 5B, the deposited carbon gapfill material may be exposed to an optional pulsed bias plasma treatment to densify the carbon gapfill material. Generally, the pulsed bias plasma treatment may be substantially similar to that described above with reference to operation 210 of method 200, and converts carbon-hydrogen bonds of the flowable carbon gapfill material to carbon-carbon bonds, thereby resulting in a higher density, and thus high quality, carbon film. In certain embodiments, operation 410 may be performed in the same chamber as operation 405. In certain embodiments, the substrate 505 and structure 500 formed thereon are transferred to a different chamber upon deposition of the flowable carbon gapfill material to perform operation 410.

In certain embodiments, operation 410 includes delivering one or more precursors to the processing region of the semiconductor processing chamber housing the structure 300 to form a treatment gas mixture. In certain embodiments, the precursors for forming the plasma include at least one of a hydrogen-containing gas such as hydrogen (H2) or ammonia (NH₃), argon (Ar), and/or helium (He). A plasma may be formed from the treatment gas mixture. The plasma may be formed within the processing region, such as by applying plasma power to the faceplate as previously described. In certain embodiments, however, the plasma may be formed external to the processing region, such as by a remote plasma source (e.g., remote plasma source unit 116 described above), and delivered to the processing region.

The source power may deliver a plasma power to the faceplate at any higher frequency, such as greater than or about 10 MHz, greater than or about 13 MHz, greater than or about 15 MHz, greater than or about 20 MHz, or higher. The source power may deliver a plasma power to the faceplate of less than or about 1500 W, and may deliver a power of less than or about 1250 W, less than or about 1000 W, less than or about 750 W, less than or about 500 W, less than or about 250 W, or less. Additionally, the source power may be pulsed at a pulsing frequency of 20 kHz or less, such as less than or about 15 kHz, less than or about 12 kHz, less than or about 10 kHz, less than or about 8 kHz, or less. Additionally, the pulsing duty cycle may be applied at less than or about 50%, and may be applied at less than or about 40%, less than or about 30%, less than or about 20%, less than or about 10%, less than or about 5%, less than or about 1% or less.

In addition to forming a plasma, biasing is applied during operation 410. To apply the biasing, a bias power source is operated at less than or about 15 MHz, or less than or about 13.5 MHz, or less than or about 10 MHz, or less than or about 8 MHz, less than or about 6 MHz, or less than or about 4 MHz, or less than or about 2 MHz, or less. The bias power supply may be operated at a power of greater than or about 600 W, and may be operated at greater than or about 800 W, greater than or about 1000 W, greater than or about 1200 W, greater than or about 1400 W, or more. Additionally, the pulsing duty cycle of the bias power source may be applied at less than or about 50%, and may be applied at less than or about 40%, less than or about 30%, less than or about 20%, less than or about 10%, less than or about 6%, less than or about 5%, less than or about 1% or less.

The bias power delivery is utilized during the treatment at operation 410 to create an amount of directionality for movement of generated plasma species, and more specifically, to create a downward movement of plasma effluents toward the structure 500. Thus, the plasma species are directed along surfaces normal to the direction of travel, such as material along the bottom of the structure 500 (e.g., bottom of the trench or aperture 525).

In certain embodiments, where the precursors at operation 410 include argon (Ar) and helium (He), argon and helium may be simultaneously delivered to the remote plasma source and/or processing region. In certain embodiments, a flow rate of argon is greater than or about 500 sccm, or greater than or about 1000 sccm, greater than or about 1500 sccm, greater than or about 2000 sccm, greater than or about 2500 sccm, or greater than or about 3000 sccm, or more. In certain embodiments, a flow rate of helium is greater than or about 500 sccm, or greater than or about 750 sccm, greater than or about 1000 sccm, greater than or about 1500 sccm, or greater than or about 2000 sccm, or more. In certain embodiments, argon may be delivered with helium at a flow rate ratio of argon to helium of greater than or about 0.5:1, and may be delivered at a flow rate ratio of greater than or about 1:1, greater than or about 1.5:1, greater than or about 2:1, greater than or about 2.5:1, greater than or about 3.0:1, greater than or about 3.5:1, greater than or about 4.0:1, or more.

In certain embodiments, operation 410 may be performed at a temperature below or about 100° C., and may be performed at a temperature less than or about 80° C., less than or about 60° C., less than or about 40° C., less than or about 30° C., less than or about 20° C., or lower. Pressure within the chamber may be kept relatively low, such as at a chamber pressure of less than or about 5 Torr, and pressure may be maintained at less than or about 1 Torr, less than or about 0.75 Torr, less than or about 0.66 Torr, less than or about 0.5 Torr, less than or about 0.25 Torr, less than or about 0.1 Torr, or less.

In certain embodiments, the pulsed bias plasma treatment at operation 410 is carried out for a period of about 5 seconds or more, or about 10 seconds or more, about 15 seconds or more, about 20 seconds or more, about 25 seconds or more, about 30 seconds or more, or more.

After performance of operation 410, operations 405 and 410 may be repeated as needed until the trench or aperture 525 of structure 500 has a desired amount of carbon gapfill material formed therein, thereby resulting in a gapfilled structure 501 as shown in FIG. 5C. And, after a desired number of repetitions of operations 405 and 410, the gapfilled structure 501 may be exposed to additional operations to fabricate a completed semiconductor device, including formation of additional structures on substrate 505 and/or annealing processes.

In summary, present disclosure provides methods and apparatus that facilitate the formation of high-quality carbon gapfill structures and that address the issues related to conventional carbon gapfill methods. In certain embodiments, the carbon gapfill methods and apparatus utilize plasma enhanced CVD (PECVD) or flowable CVD (FCVD) processes to gapfill structures with high-quality and stable carbon films.

While the foregoing is directed to embodiments of the present disclosure, other and further embodiments of the disclosure may be devised without departing from the basic scope thereof, and the scope thereof is determined by the claims that follow.

### Additional Considerations

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems may generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

While the various steps in an embodiment method or process are presented and described sequentially, one of ordinary skill in the art will appreciate that some or all of the steps may be executed in different order, may be combined or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a nonspecific plane of reference. This non-specific plane of reference may be vertical, horizontal, or other angular orientation.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

As used, the term “determining” encompasses a wide variety of actions. For example, “determining” may include calculating, computing, processing, deriving, investigating, looking up, for example, looking up in a table, a database or another data structure, and ascertaining. Also, “determining” may include receiving, for example, receiving information, and accessing, for example, accessing data in a memory. Also, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.1%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

As used, “a CPU,” “a processor,” “at least one processor” or “one or more processors” generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims.

1. A processing method, comprising:
selectively depositing a film onto a structure of a semiconductor substrate disposed in a processing region of a semiconductor processing chamber, the film comprising a carbon material;
exposing the semiconductor substrate to a pulsed bias plasma treatment to selectively densify the carbon material of the film deposited at a bottom of the structure; and
selectively etching the film from a sidewall of the structure.

2. The processing method of claim 1, wherein selectively depositing the film onto the structure comprises:
forming a plasma from a carbon-containing precursor in the processing region; and
depositing the film onto the structure with plasma effluents of the carbon-containing precursor, wherein the film is deposited into one or more gaps of the structure.

3. The processing method of claim 2, wherein the carbon-containing precursor comprises an aliphatic hydrocarbon.

4. The processing method of claim 3, wherein the carbon-containing precursor comprises 1,5-hexadiene.

5. The processing method of claim 2, wherein the carbon-containing precursor comprises a hydrocarbon with a vinyl group.

6. The processing method of claim 5, wherein the carbon-containing precursor comprises 5-vinyl-2-norbornene.

7. The processing method of claim 1, wherein exposing the semiconductor substrate to the pulsed bias plasma treatment comprises:
forming a plasma from one or more precursors in the processing region; and
biasing plasma effluents of the one or more precursors toward the structure, wherein the plasma effluents convert carbon-hydrogen bonds of the film to carbon-carbon bonds.

8. The processing method of claim 7, wherein the one or more precursors include argon and helium.

9. The processing method of claim 1, wherein selectively etching the film comprises exposing the structure to a plasma-based etch process.

10. A processing method, comprising:
forming a first plasma from a carbon-containing precursor, the formation of the first plasma remote from a processing region of a semiconductor processing chamber;
depositing a flowable film onto a structure of a semiconductor substrate disposed in the processing region with plasma effluents of the carbon-containing precursor, wherein the flowable film flows into one or more gaps of the structure;
forming a second plasma remote from the processing region; and
densifying the flowable film in the one or more gaps of the structure with plasma effluents from the second plasma.

11. The processing method of claim 10, wherein the carbon-containing precursor comprises an aliphatic hydrocarbon.

12. The processing method of claim 10, wherein the carbon-containing precursor comprises a hydrocarbon with a vinyl group.

13. The processing method of claim 10, wherein the carbon-containing precursor comprises a norbornene compound.

14. The processing method of claim 13, wherein the carbon-containing precursor comprises 5-vinyl-2-norbornene.

15. The processing method of claim 10, wherein the second plasma is formed from one or more precursors comprises at least one of argon or helium.

16. A processing method, comprising:
forming a first plasma from a carbon-containing precursor, the formation of the first plasma remote from a processing region of a semiconductor processing chamber;
depositing a flowable film onto a structure of a semiconductor substrate disposed in the processing region with plasma effluents of the carbon-containing precursor, wherein the flowable film flows into one or more gaps of the structure;
forming a second plasma in the processing region, the second plasma formed from one or more precursors comprises at least one of argon or helium; and
biasing plasma effluents from the second plasma toward the flowable film in the one or more gaps of the structure to densify the flowable film.

17. The processing method of claim 16, wherein the carbon-containing precursor comprises an aliphatic hydrocarbon.

18. The processing method of claim 16, wherein the carbon-containing precursor comprises a hydrocarbon with a vinyl group.

19. The processing method of claim 16, wherein the carbon-containing precursor comprises a norbornene compound.

20. The processing method of claim 19, wherein the carbon-containing precursor comprises 5-vinyl-2-norbornene.
